(19) United States
(12) Patent Application Publication
(10) Pub. No.: US 2010/0283449 A1
(43) Pub. Date: Nov. 11, 2010

(54) COMMUNICATION OUTLET IDENTIFICATION SYSTEM USING ETHERNET SIGNALS

(75) Inventors: Jack E. Caveney, North Palm Beach, FL (US); Ronald A. Nordin, Naperville, IL (US)

Correspondence Address: PANDUIT CORP., LEGAL DEPARTMENT, 6200 W. 175TH STREET, TINLEY PARK, IL, 60477, US

(73) Assignee: PANDUIT CORP., Tinley Park, IL (US)

(21) Appl. No.: 12/681,047

(22) PCT Filed: Oct. 13, 2008
(86) PCT No.: PCT/US2008/079723

§ 371 Date: May 17, 2010

Related U.S. Application Data
(60) Provisional application No. 60/979,283, filed on Oct. 11, 2007.

(51) Int. Cl. G01R 19/00

(52) U.S. Cl. 324/66

(57) ABSTRACT

An AC common mode backchannel signaling system is used to provide outlet ID information in a communication network. Wire pairs of a communication network are used to support the AC common mode backchannel signaling system, while also supporting Ethernet communications as well as Power Over Ethernet (PoE). Query and receiving AC circuitry is provided in an intelligent patch panel, and outlet ID receiving and response AC circuitry is provided in communication outlets. These two sets of AC circuitry use the AC common mode backchannel signaling system to communicate with one another, without disrupting PoE or Ethernet signaling on the wire pairs of the network.

### RELATED APPLICATION

The present application incorporates by reference in its entirety U.S. patent application Ser. No. 11/265,316, entitled “Method and Apparatus for Patch Panel Patch Cord Documentation and Revision,” filed Nov. 2, 2005.

### BACKGROUND OF THE INVENTION

One of the challenges faced by IT network managers is the collection and maintenance of accurate network documentation. Technologies such as Voice Over Internet Protocol (VOIP) have increased the importance of finding the identity and location of network devices (for example, in emergency situations). At the same time, it has grown more common for network devices to be powered by the communication network itself. Power Over Ethernet (PoE) is an example of this technology.

It is desirable to have systems and methods that can determine the location of network devices, while also allowing the provision of power over network cabling. It is further desirable for such a system to be compatible with PoE systems that use four wire pairs to provide PoE.

### SUMMARY OF THE INVENTION

According to one embodiment of the present invention, an AC common mode backchannel signaling system is used for identifying outlets in a communications network. Such a system can be employed in an Ethernet network, and the frequency range used for communication in the AC common-mode backchannel signaling system is relatively low compared to the frequency range used for network communications.

Systems and methods according to the present invention are compatible with Power Over Ethernet systems.

According to some embodiments of the present invention, query and receiving AC circuitry is provided in an intelligent patch panel, and outlet ID receiving and response AC circuitry is provided in communication outlet jacks. The querying and receiving AC circuitry in the intelligent patch panel communicates with the outlet jack ID receiving and response AC circuitry using AC common mode backchannel signaling over two communication wire pairs.

### BRIEF DESCRIPTION OF THE DRAWINGS

FIG. 1 is a schematic block diagram showing components and communication connections of a communication outlet identification system according to one embodiment of the present invention;

FIG. 2 is a schematic diagram showing communication connections between query and receiving AC circuitry and outlet ID receiving and response AC circuitry; and

FIG. 3 shows the use of center-tapped inductors to enable an AC common mode backchannel signaling system according to one embodiment of the present invention.

### DETAILED DESCRIPTION OF THE ILLUSTRATED EMBODIMENT

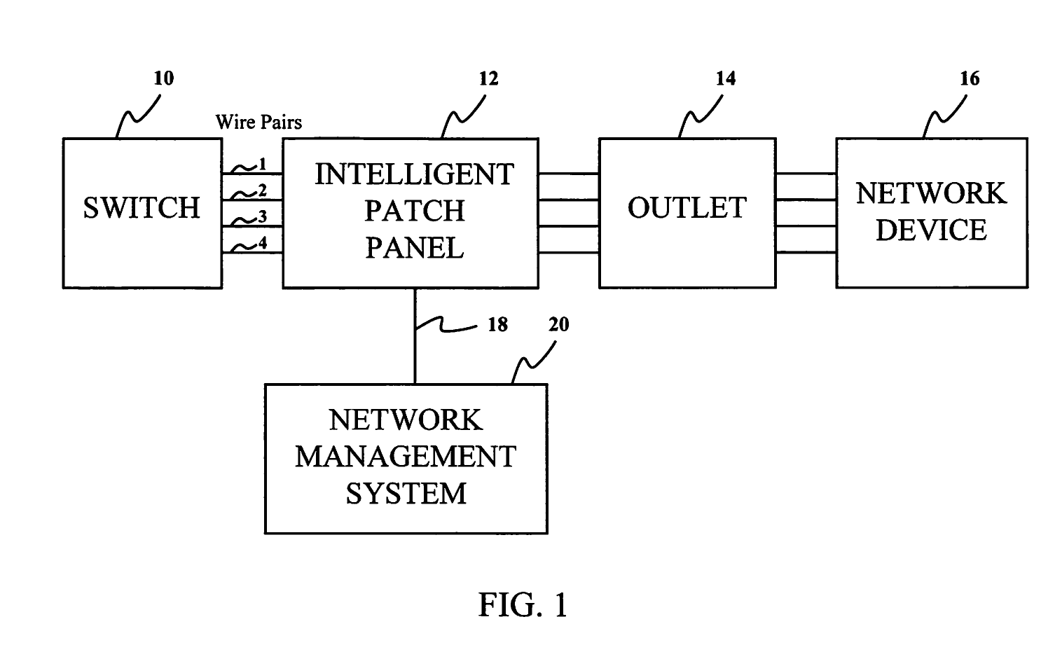

FIG. 1 is a block diagram showing system elements in a communication outlet identification system according to one embodiment of the present invention. Four wire pairs 1, 2, 3, and 4 are used for communications between network elements. A network switch 10 is connected via the wire pairs 1-4 to an intelligent patch panel 12. The intelligent patch panel 12, in turn, is connected to a communication outlet 14 via the wire pairs. The communication outlet 14 is connected to a network device 16. Examples of network devices include VOIP phones, computers, and other network end-user devices. The intelligent patch panel 12 is connected via a management link 18 to a network management system 20.

FIG. 1 shows only one communication pathway in a network, but it is to be understood that there may be several network devices, connected via several outlets, to a single intelligent patch panel 12. Further, more than one intelligent patch panel 12 may be connected to a switch 10. According to one embodiment of the present invention, the switch 10 is configured to supply PoE to network devices 16. According to another embodiment, the intelligent patch panel 12 may be configured to supply PoE to network devices 16.

Systems and methods of the present invention allow for the identification of communication outlets 14 in a communication network. This identification may be accomplished by the intelligent patch panel 12, which can forward identification (ID) information to the network management system 20 via the management link 18. Using this technique, it is possible to acquire real-time ID information on the outlets 14 in a network and thereby to maintain accurate records of the connections in the computer network at all times.

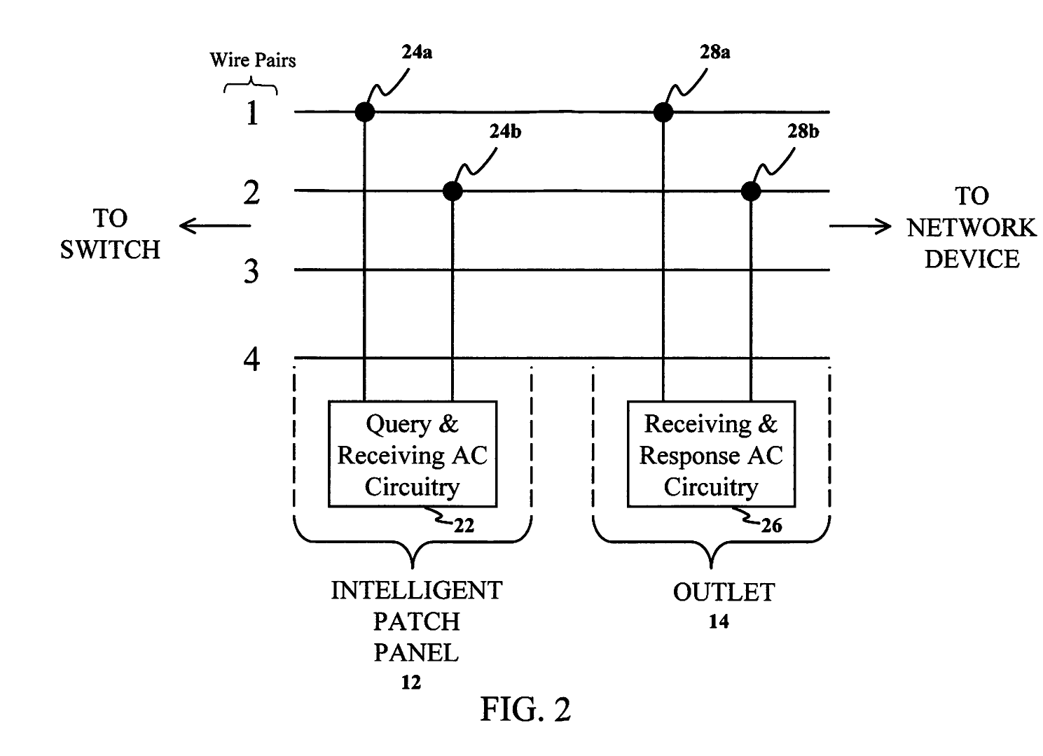

FIG. 2 illustrates connections in a computer network that enable outlet ID information to be transmitted along wire pairs in Ethernet networks that have PoE. The connections shown in FIG. 2 support an AC common mode backchannel signaling system between an intelligent patch panel 12 and a communication outlet 14. As illustrated, the first through fourth wire pairs 1-4 are used for transmitting Ethernet communications and also for transmitting PoE. Query and receiving AC circuitry 22 is provided within the intelligent patch panel 12 and is connected to the first and second wire pairs 1 and 2, respectively, at connection points 24a and 24b. Likewise, outlet ID receiving and response AC circuitry 26 is provided within a communication outlet 14 and is connected to the first and second wire pairs 1 and 2, respectively, at connection points 28a and 28b.

When an endpoint device is connected to an outlet 14, the network system detects it by the endpoint ID transmission or by the use of PoE, and this triggers the operation of the outlet ID system. The ID of an energized outlet 14 is therefore always known.

When the ID of an outlet 14 is received by the intelligent patch panel 12, the outlet ID system signals are turned off. During the short period of operation of the outlet ID system, its interference with Ethernet signaling is minimal however the Ethernet signaling could be turned off or, optionally, it could be repeated if necessary.

The outlet ID receiving and response AC circuitry 26 receives PoE constantly. The receiving and response AC circuitry 26 receives a signal from the query and receiving AC circuitry 22, which triggers a response from the receiving and response AC circuitry 26. The outlet ID receiving and response AC circuitry 26 generates an AC backchannel signal which is modulated to transmit an ID code associated with the communication outlet 14. This ID code may be provided within an ID chip in the outlet jack. The AC backchannel signal transmitted by the outlet ID receiving and response AC circuitry 26 is received by the query and receiving AC circuitry 22.

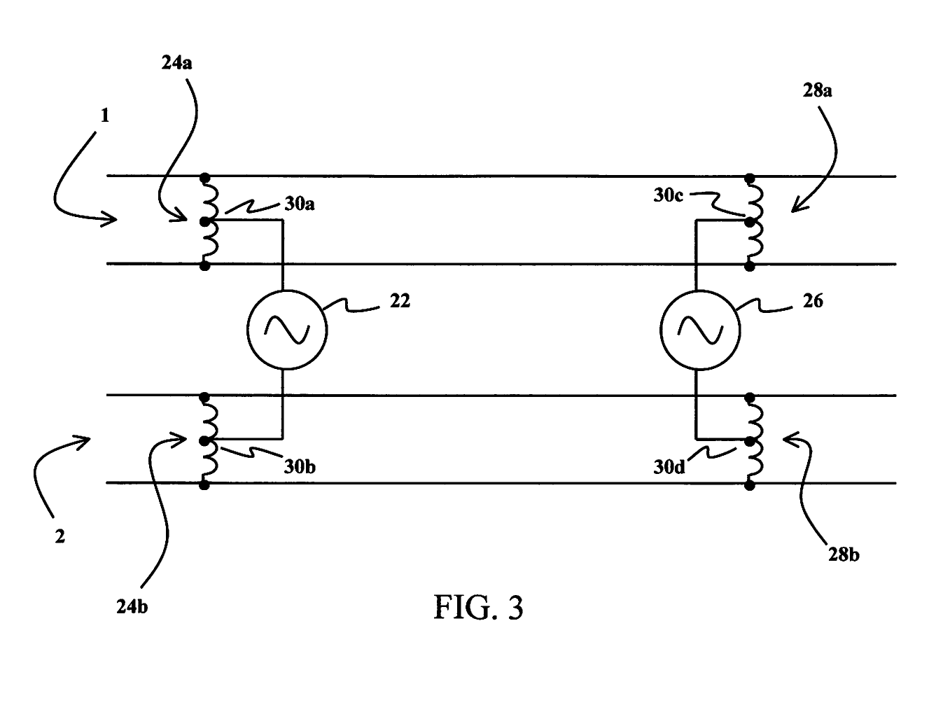

As illustrated in FIG. 3, the connections between the AC circuitry and wire pairs 1 and 2 are preferably made via center-tapped inductors 30a-30d. The center-tapped inductors pass DC PoE and the AC common mode signals, but block Ethernet signals from reaching the querying and receiving AC circuitry 22 and the outlet ID receiving and response circuitry 26. The frequency range used by the AC backchannel signaling system according to the present invention is preferably relatively low in comparison to the frequency range used for Ethernet signaling in the network.

The common mode system illustrated in FIGS. 2 and 3 utilizes two wire pairs which provide PoE. A similar common mode system can be employed utilizing the other two wire pairs to provide the ID of another jack in the same network path. For example, ID information of a jack in a downstream zone patch panel may be provided in such a system.

While particular embodiments and applications of the present invention have been illustrated and described, it is to be understood that the invention is not limited to the precise construction and compositions disclosed herein and that various modifications, changes, and variations may be apparent from the foregoing descriptions without departing from the spirit and scope of the invention. For example, while the illustrated embodiment shows the use of pairs 1 and 2 for the AC common mode backchannel signaling system, it is to be understood that other pair combinations may be employed by the system.

1. A system for communicating identification information from a communication outlet to an intelligent patch panel comprising:
query and receiving AC circuitry, the query and receiving circuitry being located in the intelligent patch panel;
receiving and response AC circuitry, the receiving and response AC circuitry being located in the communication outlet; and
at least two pairs of conductors, wherein each pair of the at least two pairs of conductors is adapted to carry a differential Ethernet signal, the at least two pairs of conductors further comprising a first pair of conductors adapted to send an AC backchannel common-mode signal from the query and receiving AC circuitry to the receiving and response AC circuitry and a second pair of conductors adapted to receive an AC backchannel common-mode signal from the receiving and response AC circuitry to the query and receiving AC circuitry.

2. The system of claim 1 further comprising center-tapped inductors connected between the first and second conductor pairs and the query and receiving AC circuitry and between the first and second conductor pairs and the receiving and response AC circuitry.

3. The system of claim 2 wherein the center-tapped inductors are adapted to pass AC backchannel common-mode signals and Power-over-Ethernet but block differential Ethernet signals.

4. The system of claim 3 wherein a frequency of the AC backchannel signal is relatively low compared to a frequency of the differential Ethernet signal.

5. The system of claim 4 wherein the at least two pairs of conductors comprises four pairs of conductors.

6. The system of claim 5 further comprising a second communication outlet, wherein the second communication outlet has a second receiving and response AC circuitry, and wherein the at least two conductor pairs comprises a third conductor pair adapted to send an AC backchannel common-mode signal from the query and receiving AC circuitry to the second receiving and response AC circuitry and a fourth pair of conductors adapted to receive an AC backchannel commode signal from the second receiving and response AC circuitry at the query and receiving AC circuitry.

7. A method of communicating identification information from a communication outlet to an intelligent patch panel comprising:
providing query and receiving AC circuitry in the intelligent patch panel;
providing receiving and response AC circuitry in the communication outlet;
providing at least two pairs of conductors, wherein each pair of the at least two pairs of conductors is adapted to carry a differential Ethernet signal, the at least two pairs of conductors further comprising a first pair of conductors adapted to send an AC backchannel common-mode signal from the query and receiving AC circuitry to the receiving and response AC circuitry and a second pair of conductors adapted to receive an AC backchannel commode signal from the receiving and response AC circuitry at the query and receiving AC circuitry;
detecting an endpoint device connected to the communication outlet; and
sending identification information from the receiving and response AC circuitry to the query and receiving AC circuitry via backchannel AC common-mode signals on the first and second pairs of conductors.

8. The method of claim 7 wherein the identification information is sent in response to a query signal from the query and receiving AC circuitry to the receiving and response AC circuitry.
